(19) United States
(12) Patent Application Publication
(10) Pub. No.: US 2025/0185448 A1
(43) Pub. Date: Jun. 5, 2025

(54) HIGH-EFFICIENCY PEROVSKITE-BASED DEVICE WITH METAL FLUORIDE INTERLAYER AND METHOD

(71) Applicant: KING ABDULLAH UNIVERSITY OF SCIENCE AND TECHNOLOGY, Thuwal (SA)

(72) Inventors: Stefaan DE WOLF, Thuwal (SA); Jiang LIU, Thuwal (SA)

(21) Appl. No.: 18/840,713

(22) PCT Filed: Feb. 21, 2023
(86) PCT No.: PCT/IB2023/051577

§ 371 Date: Aug. 22, 2024

Related U.S. Application Data
(60) Provisional application No. 63/312,896, filed on Feb. 23, 2022.

(51) Int. Cl. H10K 30/88; H10K 30/40; H10K 30/57; H10K 50/15

(52) U.S. Cl. CPC H10K 30/88; H10K 30/40; H10K 30/57; H10K 50/15

(57) ABSTRACT

A perovskite/silicon tandem device includes a silicon layer having first and second opposite sides, a first electrode located on the first side of the silicon layer, a hole transport layer located on the second side of the silicon layer, a perovskite layer located over the hole transport layer, a metal fluoride layer located over the perovskite layer and in direct contact with the perovskite layer, and a second electrode located over the ultrathin metal fluoride layer.

### CROSS-REFERENCE TO RELATED APPLICATIONS

This application claims priority to U.S. Provisional Patent Application No. 63/312,896, filed on Feb. 23, 2022, entitled “PREPARATION OF HIGH-EFFICIENT PEROVSKITE DEVICES VIA METAL FLUORIDES INTERLAYER,” the disclosure of which is incorporated herein by reference in its entirety.

### BACKGROUND OF THE INVENTION

### Technical Field

Embodiments of the subject matter disclosed herein generally relate to a perovskite-based semiconductor device having an intermediate metal fluoride layer, and more particularly, to a device that is provided with an enhanced electron extraction layer that includes the metal fluoride.

### Discussion of the Background

Perovskite solar cells are a new type of solar cell technology using metal halide perovskites as the light-absorbing materials. This kind of halide perovskite materials crystallizes as ABX₃ structures, where A refers to a monovalent cation, B is usually metallic lead or tin, and X is a halogen anion. Due to the excellent electronic properties and easy processability of the perovskite semiconductor thin film, the application of perovskite materials has been extended to the fields of light-emitting diode (LED) and also tandem devices.

At present, high-efficiency perovskite devices are based on a planar configuration with the perovskite active layer being sandwiched between two charge transport layers. When illuminated by sunlight, on the electron transport layer (ETL) side of the device, the contact electrode behaves as the negative electrode; on the contrary, on the hole transport layer (HTL) side, the corresponding electrode is the positive electrode. The state-of-art perovskite solar cells, especially those inverted perovskite with p-i-n configuration where the ETL is facing sunwards, still display an undesirably large voltage deficit, which is mainly attributed to significant surface recombination and energy level mismatches at their interfaces with ETLs.

Integrating high-performance wide bandgap perovskite solar cells onto their mainstream market-established silicon heterojunction (SHJ) counterparts is a successful strategy to reach very high-power conversion efficiencies (PCEs) due to minimized carrier thermalization losses. Since the first demonstration of such perovskite/silicon tandem solar cells in 2015, their PCE rapidly progressed, well above the records of single-junction solar cells. Although initial research focused on n-i-p tandems, recent best performing devices are mostly in the p-i-n configuration (where the n-type electron-collecting contact is facing sunwards). Early attempts to improve tandem performance focused on device optics and the search for ideal perovskite compositions.

More recently, the researchers in this field turned their attention to the interface between the perovskite and the hole transport layer (HTL) to reduce voltage losses, for instance, by molecular passivation of NiOx. Recent works also demonstrated that self-assembled monolayers (SAMs) such as 2PACz and 4Me-PACz, anchored on oxides, can yield excellent HTL/perovskite interfaces with very low V_{oc} losses [1], [2]. Despite this progress, state-of-art perovskite solar cells (PSCs)—especially those employing wider-bandgap perovskites (e.g., ˜1.68 eV as frequently used for tandem applications)—still suffer from an undesirably large V_{oc} deficit. This mainly stems from significant carrier recombination and an energy level mismatch at their interface with the electron transport layer [3] to [5], which most commonly consists of evaporated fullerene (C₆₀). Insertion of an ultrathin LiF layer at the perovskite/C₆₀ interface has been suggested to alleviate this issue, yet this may result in reduced device stability, which is usually attributed to its deliquescent behavior [1], [6].

Thus, to further improve the performance of the perovskite single-junction devices and also perovskite/silicon tandem, developing a strategy to modify the perovskite/ETL interface is highly desirable.

### SUMMARY OF THE INVENTION

According to an embodiment, there is a perovskite/silicon tandem device that includes a silicon layer having first and second opposite sides, a first electrode located on the first side of the silicon layer, a hole transport layer located on the second side of the silicon layer, a perovskite layer located over the hole transport layer, a metal fluoride layer located over the perovskite layer and in direct contact with the perovskite layer, and a second electrode located over the ultrathin metal fluoride layer.

According to another embodiment, there is a transceiver for transmitting or receiving an encoded light beam, the transceiver including a tandem device configured to convert the encoded light beam into pairs or electrons and holes or to convert pairs of electrons and holes into the encoded light beam, a processor connected to the tandem device and configured to decode the light beam when the light beam is received, and to encode the light beam when the light beam is transmitted, and a power source configured to supply power to the tandem device and the processor. The tandem device includes a silicon layer having first and second opposite sides, a first electrode located on the first side of the silicon layer, a hole transport layer located on the second side of the silicon layer, a perovskite layer located over the hole transport layer, an ultrathin metal fluoride layer located over the perovskite layer and in direct contact with the perovskite layer, and a second electrode located over the ultrathin metal fluoride layer.

According to yet another embodiment, there is a single junction device that includes a substrate, a first electrode located over the substrate, a hole transport layer located on the substrate, a perovskite layer located over the hole transport layer, an electron transport layer that includes an ultrathin metal fluoride layer located over the perovskite layer and in direct contact with the perovskite layer, and a second electrode located over the ultrathin metal fluoride layer.

### BRIEF DESCRIPTION OF THE DRAWINGS

For a more complete understanding of the present invention, reference is now made to the following descriptions taken in conjunction with the accompanying drawings, in which:

FIGS. 1A and 1B are schematic diagrams of a perovskite/silicon tandem solar cell having a metal fluoride ultrathin layer on the perovskite material;

FIGS. 2A and 2B are cross-sectional scanning electron microscope images for the bottom Si cell and the perovskite/silicon tandem, respectively;

FIG. 3 is a flow chart of a method for forming the perovskite/silicon tandem with a metal fluoride layer on top of the perovskite layer;

FIG. 4 is a schematic diagram of a perovskite solar cell having a metal fluoride ultrathin layer on the perovskite material;

FIGS. 5A and 5B show the valence band (VB) and photoelectron cut-off region of the perovskite, and perovskite/1 nm-interlayer using ultraviolet photoemission spectroscopy (UPS) and low energy inverse photoemission spectroscopy (LE-IPES) spectra for samples deposited on IZO/2PACz coated c-Si substrates;

FIGS. 6A and 6B show experimentally determined energy level diagrams of the ETL-side interface with and without an MgFₓ insertion layer;

FIGS. 7A and 7B illustrate the X-ray photoelectron spectroscopy (XPS) spectrum and the elemental composition ratio of samples having the metal fluoride layer formed on top of the perovskite layer;

FIG. 8 illustrates a histogram of the quasi-Fermi-level splitting (QFLS) values in the perovskite layer;

FIG. 9 illustrates the J-V curves for the tandem solar cell with an ultrathin metal fluoride layer formed on the perovskite layer;

FIG. 10A illustrates a histogram of the V_{oc} for the above noted tandem solar cell and FIG. 10B illustrates the PCE of the same tandem solar cell;

FIG. 11 illustrates the stabilized power output of one MgFₓ-based tandem device, certified by Fraunhofer ISE CalLab;

FIG. 12 illustrates reconstructed pseudo JV characteristics of the MgFₓ-based tandem device; and

FIG. 13 illustrates a transceiver/light emitting device that uses the MgFₓ-based tandem device.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a perovskite/silicon tandem solar cell having an ultrathin magnesium fluoride, MgFₓ, layer, with x smaller than 2, located between the perovskite material and the ETL layer. However, the embodiments to be discussed next are not limited to tandem solar cells, or MgFₓ layers, but may be applied to other perovskite-based device and/or other metal fluoride layers.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

According to an embodiment, a novel perovskite/silicon tandem solar cell having a metal fluoride layer MgFₓ is used as an interlayer at the perovskite/ETL interface to suppress the interfacial recombination, leading to an improved electron extraction and device performance. Other metal flouride layers have been investigated and found to also be effective. This approach is also implemented in other perovskite-based devices, for example, PSC, photodetectors, light emitting devices, etc. The ultrathin nature of the evaporated MgFₓ layer can spatially separate photogenerated electrons and holes to reduce recombination at the perovskite/ETL interface without compromising the electron extraction.

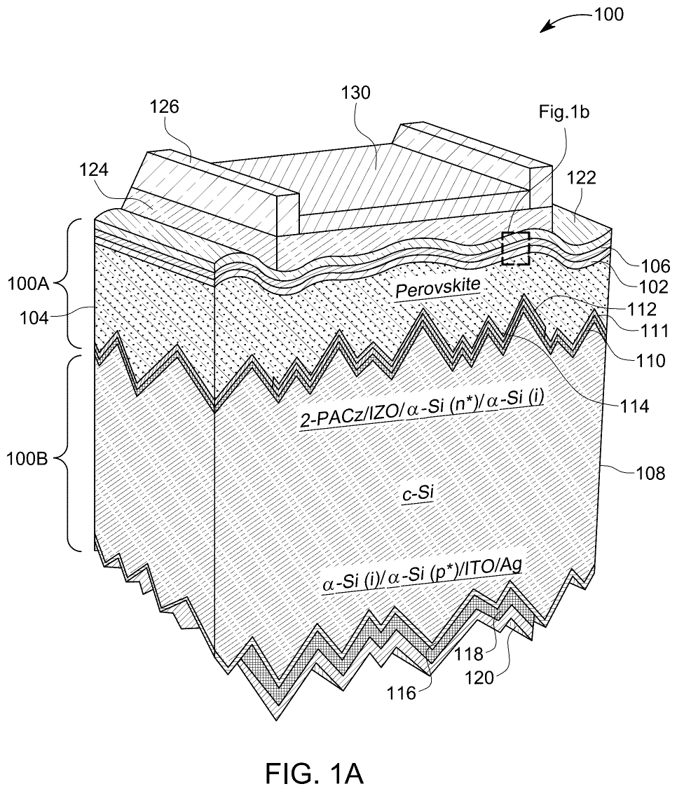

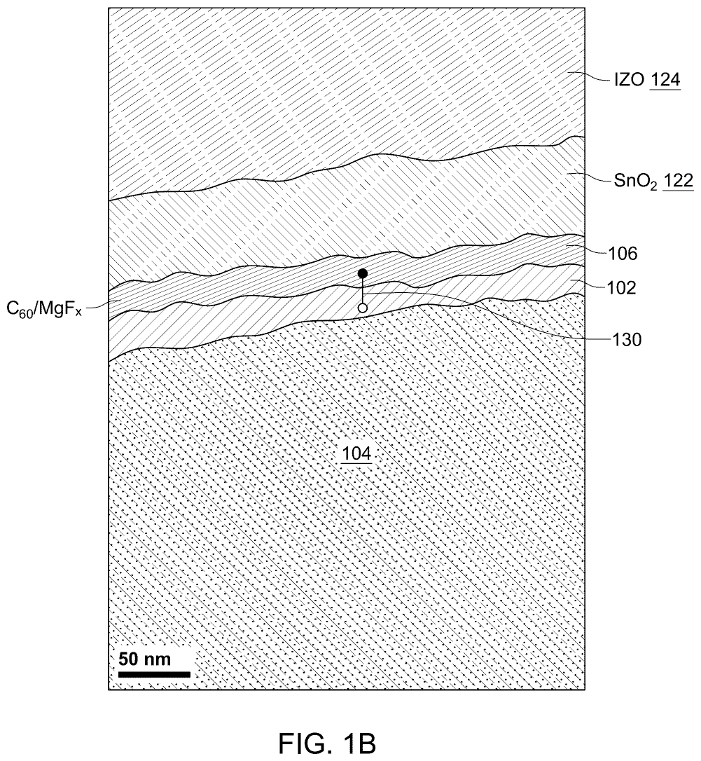

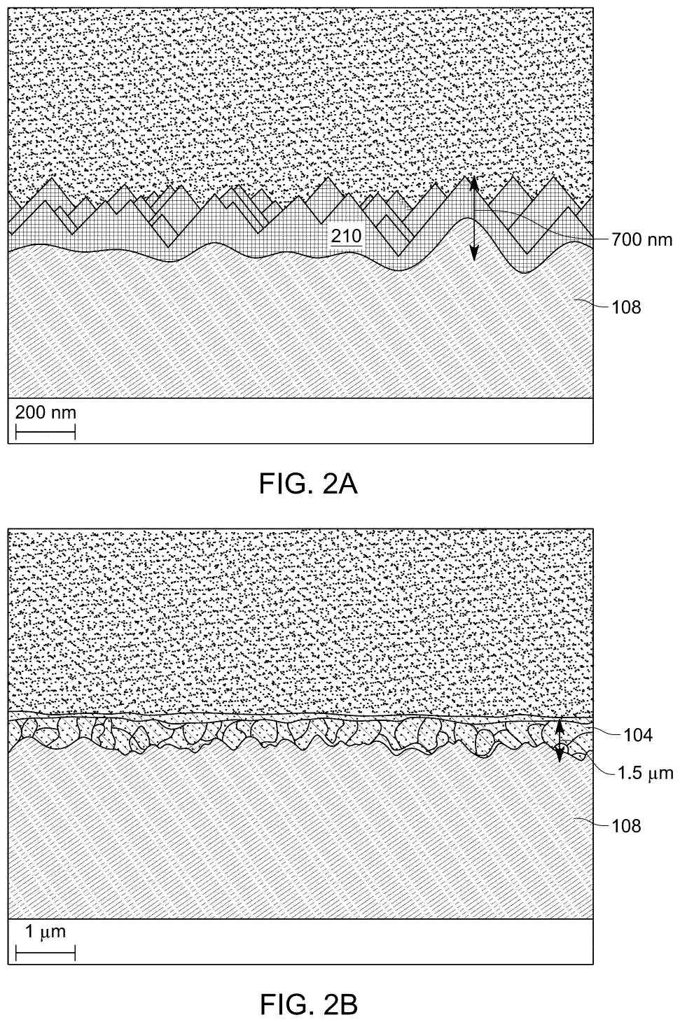

FIGS. 1A and 1B schematically illustrate a perovskite/silicon tandem solar cell 100 having a first perovskite-based solar cell 100A located on top of a second Si-based solar cell 100B. The perovskite-based solar cell 100A includes an ultrathin metal fluoride layer 102, which is used as an interlayer between a perovskite layer 104 and an electron-selective interface layer 106 (also called an electron transport layer, ETL). The perovskite layer 104 may include any known perovskite, for example, Cs_{0.05}FA_{0.8}MA_{0.15}Pb(I_{0.755}Br_{0.255})₃, while the ETL layer may include C₆₀. The heterojunction Si solar cell 100B includes a crystalline c-Si layer 108 facing the perovskite layer 104 through a layer 110 of intrinsic α-Si, a layer 111 of n-doped α-Si, a layer 112 of indium zinc oxide (IZO), and a layer 114 of ([2-(9H-carbazol-9-yl)ethyl]phosphonic acid), 2PACz. The monolithic perovskite/silicon tandem solar cell 100 is built onto the SHJ bottom cell 100B, using crystalline silicon wafers 108 with double-side texture. The texture of the c-Si layer 108 is illustrated in FIG. 2A, which is a cross-sectional SEM image of the Si bottom cell 100B, and also in FIG. 2B, which is a cross-section SEM image of the perovskite/silicon tandem 100. Note that FIG. 2A shows plural protuberances 210 (pyramids in this embodiment) extending with various heights, in the hundreds of nm range, but smaller than one μm, from the bulk of the Si layer. FIG. 2B shows the top portion of the c-Si layer 108 and its protuberances 210 being covered and filled in by the perovskite layer 104.

The perovskite/silicon tandem solar cell 100 further includes plural layers formed on the bottom of the c-Si layer 108. In this embodiment, the bottom of the c-Si layer 108 is covered with a layer 116 including a sub-layer of intrinsic α-Si and a sub-layer of p-doped α-Si, a layer 118 of indium tin oxide (ITO), and an electrode 120, made, for example, of Ag. At this side/face of the tandem device 100, the holes are extracted and collected by the electrode 120. At the opposite face of the device 100, on the perovskite layer side, a buffer layer 122, for example, a layer of SnO₂, is formed over the electron selection layer 106, and a transparent layer 124, for example, IZO layer, is formed over the buffer layer 122. An electrode 126 may be formed on top of the IZO layer for collecting the electrons.

In this embodiment, the metal fluoride layer 102 may be a MgFₓ layer, with x smaller than 2, for example, between 0.8 and 1.2. The metal fluoride layer is a stable inorganic compound that is frequently used in the field of optics due to its high transparency over extremely wide range of wavelengths, and therefore is commercially available at low cost. It is noted that the MgFₓ layer is manufactured so that x is between 0.8 and 1.2 in the embodiment of FIG. 1A. It is also noted that a MgF₂ layer may not achieve the same results as the layer 102 as only the MgFₓ layer 102 forms vertical dipoles 130, as illustrated in FIG. 1B, in the space between the perovskite layer 104 and the electron selection layer 106. The full circle of the dipole 130 indicates a negative electric charge while the empty circle of the dipole 130 indicates a positive electric charge. Because of the formation of the vertical electric dipoles 130 just on top of the perovskite layer 104, an interfacial energy-level alignment towards electron extraction is achieved, as discussed later. Note that a traditional layer of MgF₂ would not achieve such dipoles, and thus, such an alignment.

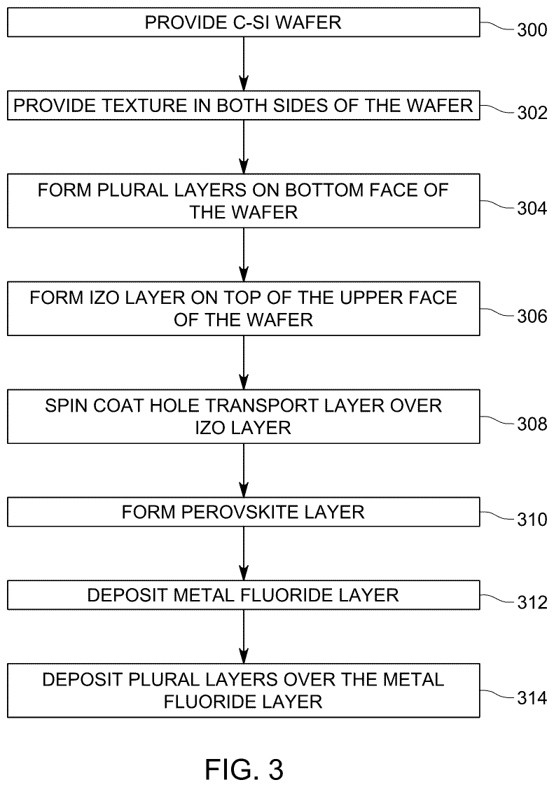

To achieve the MgFₓ layer 102 with x between 0.8 and 1.2, the following method illustrated in FIG. 3 was employed. The materials used to make the device 100 may include: lead iodide (PbI₂, 99.999%), lead bromide (PbBr₂, 99.999%), formamidinium (FA), formamidinium iodide (FAI), methylammonium (MA), methylammonium bromide (MABr), Cesium iodide (CsI, 99.999%), anhydrous dimethylformamide (DMF, anhydrous, 99.8%), anhydrous dimethyl sulfoxide (DMSO, anhydrous, ≥99.9%), anhydrous chlorobenzene (CB, anhydrous, 99.8%), lithium fluoride (LiF), sodium fluoride (NaF), [2-(9H-carbazol-9-yl)ethyl]phosphonic acid (2PACz), C₆₀ (>99.5% purity), bathocuproine (BCP, 99.5% purity), and ceramic 2-inch IZO.

In step 300, a c-Si wafer was provided and this was used as the layer 108. The Si bottom cell 108 was obtained by using a 4-inch n-doped float-zone (FZ) Si wafer with a thickness of 260-280 μm. The double-side texture structure of the layer 108 with random distributed pyramids 210 was obtained in step 302 using an alkaline solution. The size of the pyramids 210 is controlled by adjusting the alkaline concentration and the process temperature. The wafers were dipped in hydrofluoric acid solution followed by a cleaning process, before being transferred into a plasma enhanced chemical vapour deposition (PECVD) cluster for amorphous silicon (a-Si) deposition. In step 304, 8 nm intrinsic (i), 6 nm n-doped, and 13 nm p-doped a-Si layer 116 was grown on the bottom face of the wafer 108 using the PECVD cluster tool. The process temperatures are 200° C. In the same step, 150 nm ITO 118 and 250 nm Ag 120 were sputtered on the backside of the wafer through a shadow mask of 1.1×1.1 cm². In step 306, 15 nm IZO 112 recombination junction was sputtered on the front side/face of the wafer through an aligned mask with an opening area of 1.1×1.1 cm². In order to recover sputtering damage, an annealing step at 200° C. for 10 min was carried out. The wafer was then laser-cut to 2.2 cm×2.2 cm square substrate for tandem fabrication.

The perovskite top cell 100A fabrication on the Si bottom cell 100B is now discussed. The Si bottom wafer 108 was subjected to UV-Ozone treatment for 10 min before being transferred into a glovebox. For 2PACz 114 deposition, 1 mg/mL 2PACz in ethanol was used. The 2PACz layer 114, which acts as a hole transport layer (HTL) was spin-coated in step 308 on the IZO layer 112 at 5000 rpm for 30 s, followed by drying at 100° C. for 10 min. In step 310, 1.7 M Cs_{0.05}FA_{0.8}MA_{0.15}Pb(I_{0.755}Br_{0.255})₃ perovskite precursor solution was prepared by dissolving a mixture of FAI, MABr, CsI, PbI₂, and PbBr₂ in a mixed solvent of DMF and DMSO with a volume ratio of 4:1. The perovskite film 104 was spin-coated at 2000 rpm for 45 s an acceleration of 400 rpm/s, then followed with 7000 rpm for 10 s with an acceleration of 5000 rpm/s. Chlorobenzene of 200 μL was dropped in the center of the substrates 12 s before the end of the spin-coating process. After the rotation ceased, the substrates were immediately transferred onto a hotplate of 100° C. and were annealed for 15 min. After perovskite deposition, a layer 102 of about 1 nm metal fluorides (NaF, LiF, MgFₓ or CaFₓ) was deposited in step 312 by thermal evaporation directly onto the perovskite layer 104. The sample was then quickly transferred to a C₆₀ evaporation chamber to minimize air exposure as much as possible. During the transfer process, the sample may be exposed to air for a short period of time, but the inventors did not find that this process affected the device performance. In step 314, 15 nm C₆₀ 106 was subsequently deposited by thermal evaporation. In the same step, 20 nm SnO₂ 122 was then deposited by atomic layer deposition (ALD) using a Picosun system. The substrate temperature was maintained at 100° C. during ALD deposition with TDMASn precursor source at 80° C. and H₂O source at 18° C. The pulse and purge time for Tetrakis(dimethylamino)tin(IV) (TDMASn) is 1.6 and 5.0 s with a 90 sccm carrier gas of nitrogen, for H₂O is 1.0 and 5.0 s with 90 sccm N₂. 140 cycles were used. Still in the same step, 70 nm IZO 124 was sputtered from a 3-inch IZO ceramic target on top of the SnO₂ through a shadow mask. Ag finger 126 with a thickness of 500 nm was thermally evaporated using a high precision shadow mask. Finally, 100 nm MgFₓ layer 130 was thermally evaporated as an anti-reflection layer. The thickness of the C₆₀, IZO and metal fluoride layers were first calibrated by spectroscopic ellipsometry. The evaporation rate and thickness of each experiment were monitored by quartz crystal microbalance sensors.

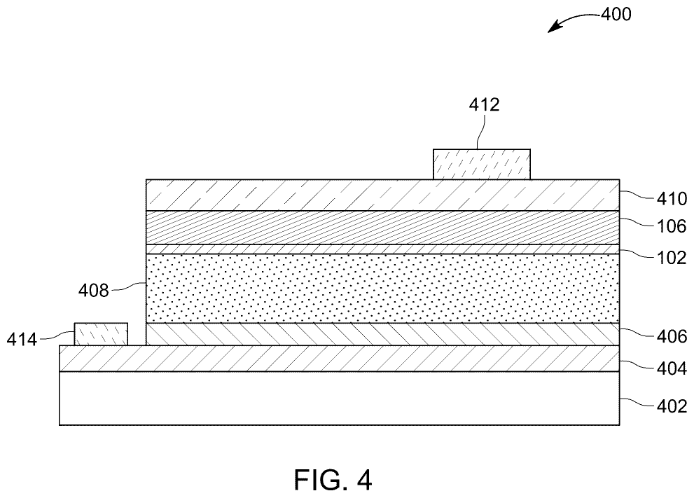

An alternative structure, a single-junction perovskite solar cell 400 as illustrated in FIG. 4, was also fabricated with the ultrathin metal fluoride layer 102 as now discussed. The single-junction perovskite solar cell 400 includes a substrate 402, for example, made of glass, on which a layer 404, for example, ITO, is located. The ITO glass was ultrasonically cleaned with detergent, deionized water, acetone, and isopropanol successively, and then blow-dried with compressed nitrogen. The substrate was subjected to UV-Ozone treatment for 10 min before any film deposition. The processes for HTL and perovskite are the same as that for tandem device 100. Alternatively, the ITO glass was spin-coated with a thin layer 406 of a self-assembled monolayer (SAM) 2PACz (the hole transport layer) at 5,000 r.p.m. for 30 s followed by annealing at 100° C. for 10 min (0.5-1.0 mg/mL in Ethanol). A mixture of perovskite solution (1.5 M) composed of mixed cations (Pb, Cs, FA, and MA) was dissolved in a mixed solvent (dimethylformamide (DMF)/dimethylsulfoxide (DMSO) with 4/1 ratio), according, for example, to a formula of Cs_{0.03}(FA_{0.90}MA_{0.10})_{0.97}PbI₃. A two-step spin-coating procedure with 2,000 r.p.m. for 40 s and 6,000 r.p.m. for 10 s was adopted to prepare the perovskite film 408. In one embodiment, the perovskite film 408 is made to have the same chemical composition as the film 104 in FIGS. 1A and 1B. Anisole (300 μl) was dropped on the spinning substrate during the last 10 s of the second spin-coating step. Subsequently, the sample was annealed at 100° C. for 30 to 60 min. After the perovskite deposition, the sample was transferred into a thermal evaporator for the metal fluoride layer 102, the C₆₀ (25 nm) layer 106 and the BCP (5 nm) layer 410 deposition. For the final step, a 120 nm thick Ag or Cu layer 412 was evaporated at low pressure (<10⁻⁶ Torr) with an area of ˜0.1 cm² to form the top electrode. A similar bottom electrode 414 may be formed on the ITO layer 404. The methods discussed herein for forming the device 100/400 may also be used for making photodetectors and other devices that use a perovskite layer.

For testing purposes, the tandem device 100 was sandwiched between two 3-mm-thick cover glass/encapsulant with black butyl rubber sealant at the edges. The device was vacuum-laminated in an industrial laminator at 120° C. for 20 min. Tinned plated copper strips were used to contact the upper and lower electrodes of the tandem device using Ag paste, and were extended to the outside of the cover glass. For damp heat test, the devices were placed inside an environmental chamber with a condition of 85° C. and 85% relative humidity, and were taken out for J-V measurement at some intervals.

The inventors verified the ultrathin (which is defined herein as being less than 2 nm thickness) nature of the fluoride-based interlayer 102 inserted at the electron-selective top contact with cross-sectional high-resolution scanning transmission electron microscopy (HR-STEM), as illustrated in FIG. 1B. The magnified STEM images and energy-dispersive X-ray (EDX) spectroscopy mapping clearly outline the perovskite/MgFₓ/C₆₀/SnO₂/IZO top contact structure, identifying the presence of a ˜15 nm C₆₀ layer and a ˜20 nm SnO₂ layer. Note that the SnO₂ layer acts as a buffer against damage from sputtering of the IZO transparent top electrode 124. Notably, in spite of its ultrathin nature, the evaporated MgFₓ layer 102 forms a continuous layer on top of the perovskite layer 104, as proven via a plan-view specimen (not shown). Since the fluoride-based interlayer 102 is thermally evaporated onto the perovskite layer 104, translating this process to large-area perovskite/silicon tandems is expected to be easy to implement, compared to solution processed interlayers as previously reported.

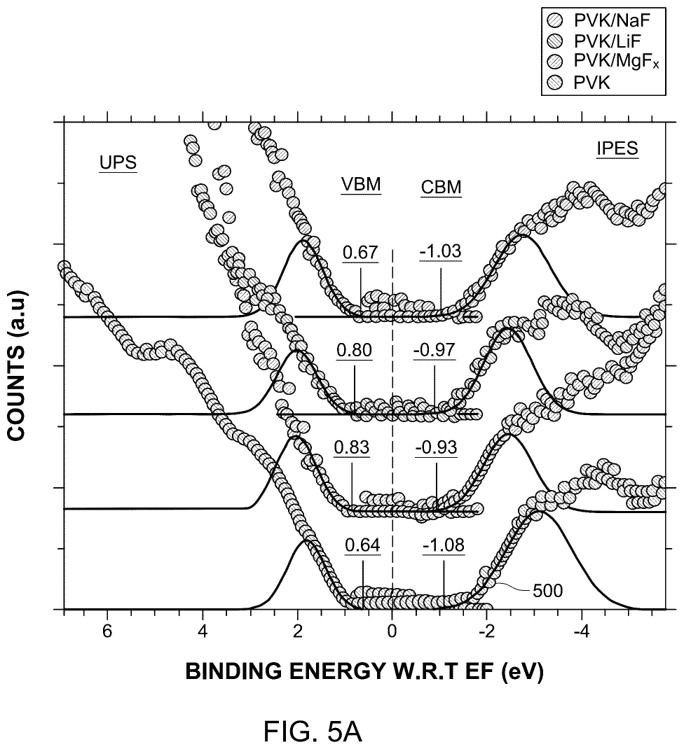

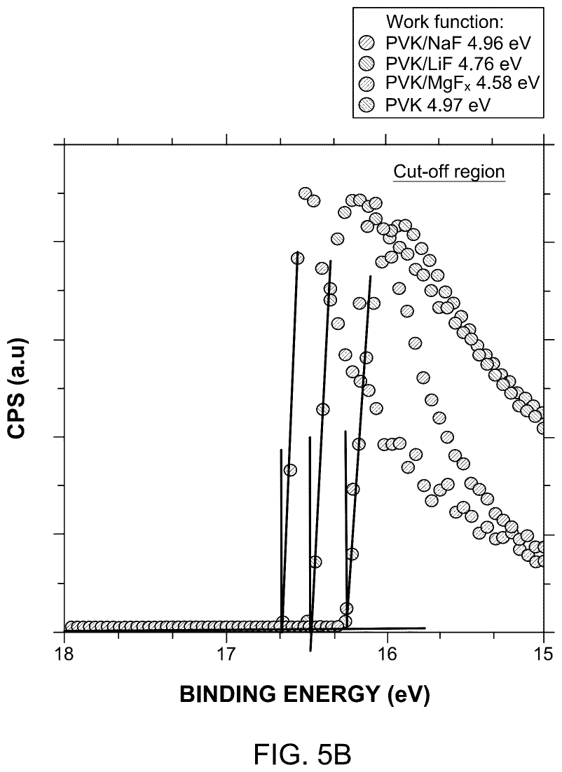

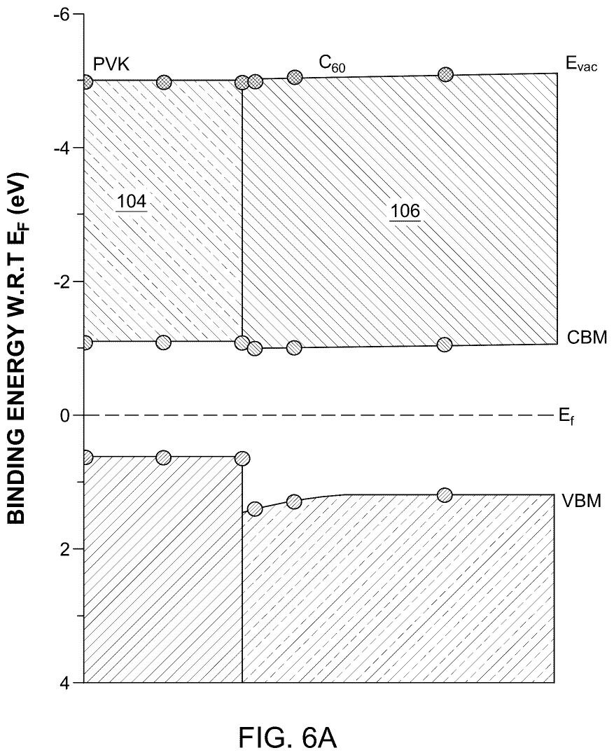

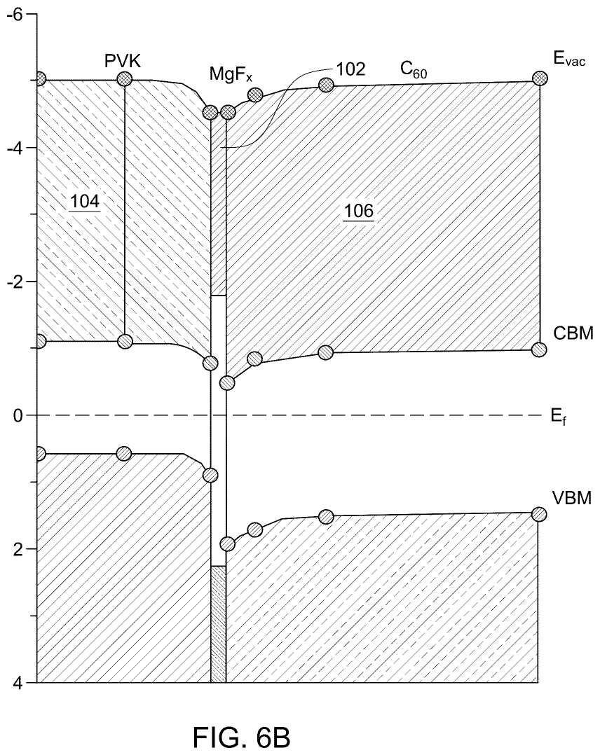

The inventors also investigated the energy level alignment of the perovskite layer 104 with the NaF, LiF and MgFₓ overlayers 102 by ultraviolet photoemission spectroscopy (UPS) and low energy inverse photoemission spectroscopy (LE-IPES) for occupied and unoccupied states, respectively. As shown in FIGS. 5A and 5B, the work function (WF) of the bare perovskite (see FIG. 5B) is around 4.97 eV; by coating this layer with a thin fluoride-based layer, the WF systematically shifts towards smaller values. The inventors found that the MgFₓ layer 102 caused the largest WF shift with 0.39˜0.50 eV (see FIG. 5B). With the presence of fluoride interlayers, the valence band maximum (VBM) of the perovskite, determined with a Gaussian fitting method, is lowered relative to the Fermi level (EF), implying that the fluorides cause a downward band bending at the perovskite interface, which is favorable for electron extraction. The downward band bending was also confirmed by a small shift (0.1 eV) in the perovskite Pb4f and I3d core levels. To evaluate such band bending as a function of ETL thickness, in-situ UPS/LE-IPES measurements were conducted, enabling sketching of the band structure at the perovskite/ETL interface, as illustrated in FIGS. 6A and 6B. The perovskite/C₆₀ sample (shown in FIG. 6A) without the metal fluoride layer 102 displays negligible band bending, which is consistent with previous work on the MAPbI₃/C₆₀ interface. However, the inventors found that with the presence of a MgFₓ interlayer 102, the conduction band of the C₆₀ layer 106 (identified as the lowest unoccupied molecular orbital, LUMO) clearly bends down toward the perovskite interface as illustrated in FIG. 6B, which implies that the MgFₓ layer may promote the formation of electron-selective contacts with low interfacial resistance.

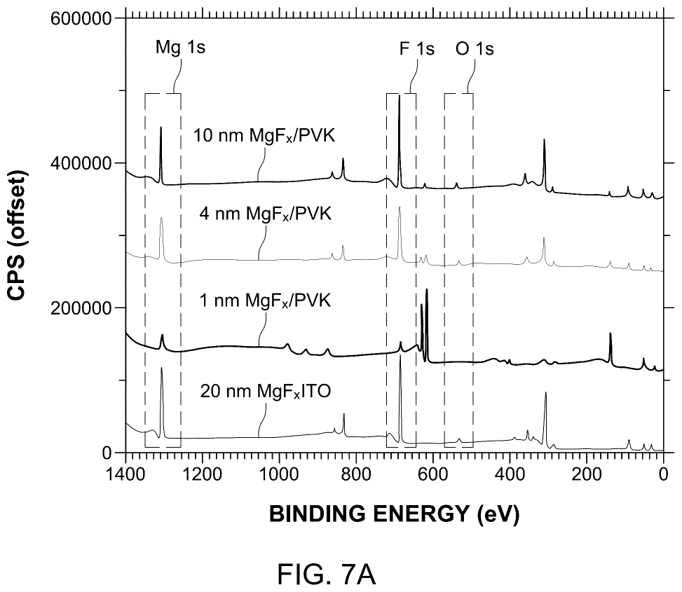

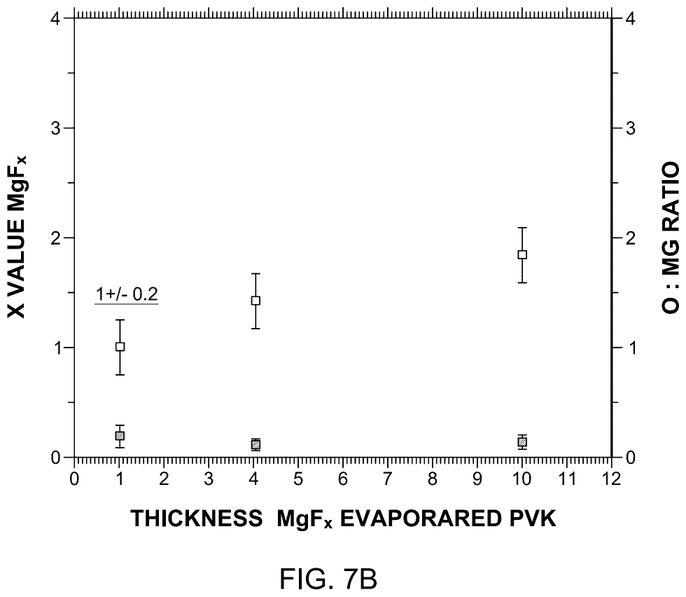

X-ray photoelectron spectroscopy (XPS) results illustrated in FIGS. 7A and 7B show that the evaporated ultra-thin (˜1 nm) MgFₓ films 102 strongly deviate from their bulk stoichiometric (x=2) composition, with an x value in the range 1±0.2. Near-stoichiometric MgFₓ films are found above a film thickness of 6-10 nm. This sub-stoichiometric nature is producing the vertical electric dipole 130 in this layer (shown in FIG. 1B), aiding interfacial energy-level alignment towards electron extraction. The presence of a surface dipole at the metal-fluoride/C₆₀ interface can increase the local work function and hinder efficient electron extraction. The z-component of the dipole moment (Dz) is calculated to be maximal for a formamidinium lead iodide FAPI/C₆₀ system (7.24 Debye) and is significantly reduced by the insertion of an interlayer, falling to 2.07 Debye for the (LiF) n-inserted case and 1.45 Debye for the (MgFₓ) n-inserted case. This trend is consistent with the trend in the work functions measured experimentally, making the (MgFₓ)ₙ-inserted case to have the highest efficiency. At the interlayer/C60 contact, the strongly electronegative F-atoms in the interlayer draw electron density from the C-atoms of the C₆₀ molecule, and thus induces positive charge on C₆₀, as estimated by Bader charge analysis. Evidently, the (MgFₓ)ₙ layer acts as a better electron sink than the (LiF) n layer, as judged by the Bader charges of −1.56e in the interlayer and +0.11e in C₆₀ for the (LiF)ₙ case, as compared to −2.12e in the interlayer and +0.13e in C₆₀ for the (MgFₓ)ₙ case. This facilitates efficient charge extraction from the perovskite layer, more so in the (MgFₓ)ₙ case than the (LiF)ₙ case.

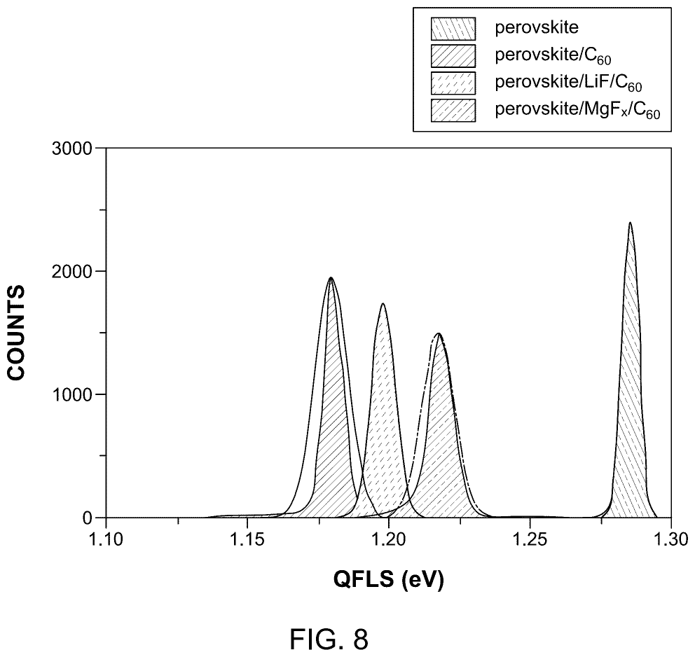

To verify these findings from the carrier-dynamics perspective, the inventors quantified the non-radiative recombination losses at the perovskite/ETL interfaces via hyperspectral absolute photoluminescence (PL) imaging under 1-sun equivalent illumination. This allows to extract the quasi-Fermi-level splitting (QFLS or Δμ) values in the perovskite layer, which is related to the internal voltage of complete devices. FIG. 8 shows that the mean QFLS of IZO/2PACz/perovskite structures without ETL is around 1.285 eV, and the IZO/2PACz/perovskite/C₆₀ sample exhibited a sharp decline of QFLS with a mean value of 1.119 eV. The LiF- and MgFₓ-treated samples display QFLS values of 1.198 and 1.217 eV, respectively. Considering that the HTL side remained unchanged, the inventors associate the undesired QFLS quenching with trap-assisted recombination at the perovskite/ETL interface. Earlier reports have shown that due to structural disorder or molecular imperfections, fullerene-based ETLs commonly have a strong band tail state, which may interact electronically with the perovskite layer to form recombination channels. Based on these findings, it is believed that an advantageous role of the ultrathin MgFₓ layer is the blocking of gap-state assisted recombination channels, suppressing charge recombination at the perovskite/ETL interface.

Next, time-resolved photoluminescence (TRPL) spectroscopy further reveals that the IZO/2PACz/perovskite structure shows a very slow decay process, with an average carrier lifetime of ˜1.6 μs, attesting to the high quality of the perovskite film 104 and the excellent surface passivation on its HTL side. The inventors found that coating the C₆₀ directly onto the perovskite causes a large reduction in the PL lifetime. However, the use of the MgFₓ interlayer between the perovskite and the C₆₀ layers prolongs the average PL decay time to a substantial extent, compared to the perovskite/C₆₀ sample, indicating significant suppression of the non-radiative recombination.

Further, the inventors quantified the surface recombination velocity (Sf) and also the electron-hole diffusion lengths in the perovskite films via transient absorption spectroscopy (TAS). It was observed a sharp negative band peaking at 718 nm and 710 nm for bare and C₆₀-coated perovskite samples, respectively, which can be assigned to ground-state photobleaching. As expected, the intensity of perovskite/MgFₓ/C₆₀ structures is remarkably enhanced compared to their perovskite/C₆₀ counterparts. By globally fitting the TA decay curves of the three samples under four laser excitation conditions to a diffusion equation (see FIG. 8), the inventors found the electron-hole diffusion length to be around 12 μm, which is much longer than the perovskite thickness, as desired for efficient solar cells. Moreover, the inventors found that the Sf is as high as 1.93×10⁴ cm/s for the perovskite/C₆₀ sample. When the MgFₓ interlayer was used, Sf quickly decreased to 7.6×10³ cm/s. This further demonstrates that the trap states that cause non-radiative recombination mainly come from the perovskite interface with the ETL, rather than its bulk.

To verify the improved charge extraction at the perovskite/C₆₀ interface, the inventors first fabricated the single-junction p-i-n device 400 with fluoride-based interlayers, as well as control samples without the interlayer. The inventors found that the solar cell with the MgFₓ interlayer reaches a V_{oc} of 1.23 V, representing a ˜50 mV absolute enhancement when compared to the control sample. This is also ˜20 mV higher than when using a LiF interlayer. These results agree well with the energy-level and surface-passivation analyses noted above. Notably, the FF also improved, reaching 81.1%, which is likely attributable to enhanced surface passivation at maximum-power point conditions.

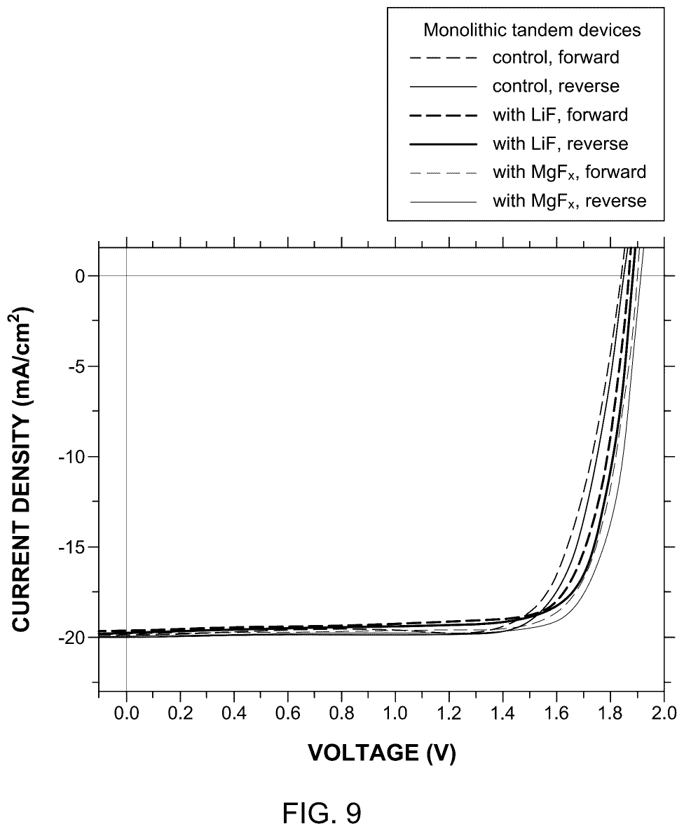

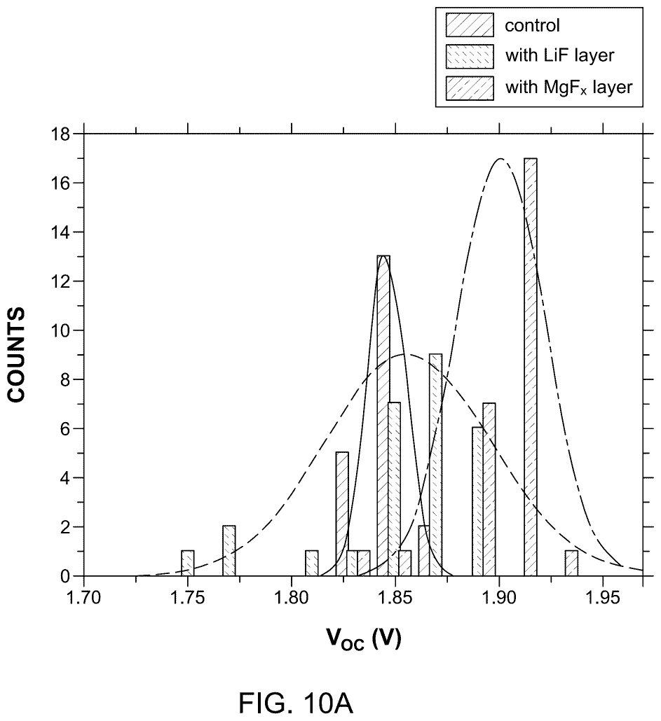

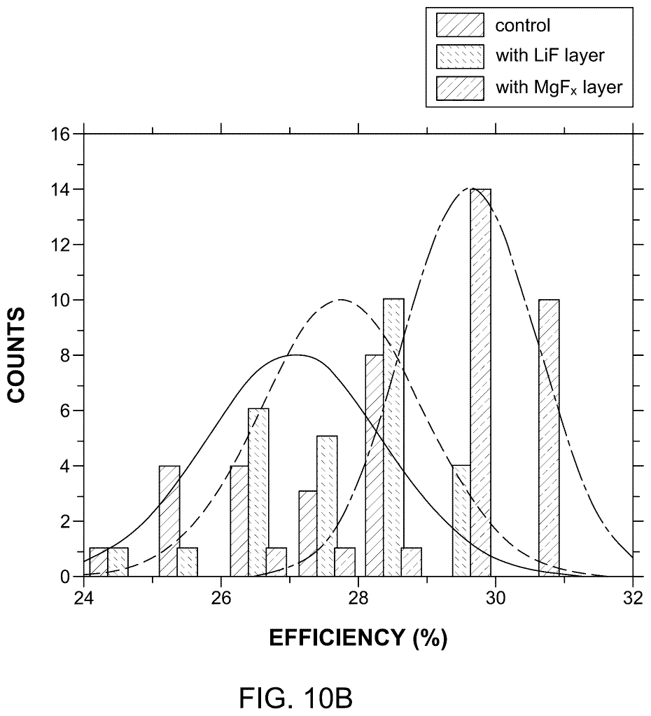

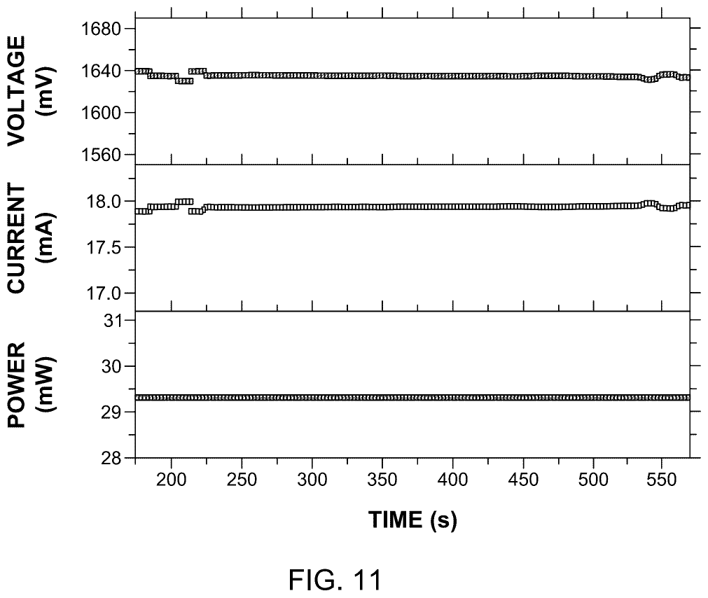

Then, the inventors fabricated monolithic perovskite/silicon tandem solar cells 100 for testing. As shown in FIG. 9, the MgFₓ-based devices show a remarkable reverse-scan PCE of up to 30.5% with a short-circuit current density, J_{sc} of 19.76 mA/cm², a V_{oc} of 1.92 V, an FF of 80.7%. The control tandem showed a best PCE of 28.6% with a J_{sc} of 19.84 mA/cm², a V_{oc} of 1.85 V, an FF of 77.9% under reverse scan. The device statistics (shown in FIGS. 10A and 10B) corroborate that the PCE improvement is mainly due to the enhanced V_{oc} and FF values. One unencapsulated MgFₓ-based tandem device was certified at Fraunhofer ISE CalLab, showing a reverse-scan PCE of 29.42% with a J_{sc} of 19.84 mA/cm², a V_{oc} of 1.91 V, an FF of 77.6%, and a steady-state PCE of 29.30% (see FIG. 11), representing the highest value in openly published literatures for perovskite/silicon tandems. Integrating the calibrated EQE over the AM1.5G spectrum yields J_{sc} values of 19.95 and 19.77 mA/cm² for the perovskite and c-Si subcells, respectively, which agrees with the tandem J_{sc} values of ˜19.8 mA/cm², again representing one of the highest values in literature within its class. The optical analysis revealed that the optical loss, in addition to some reflection, mainly comes from parasitic absorption in the top transparent conductive oxide (TCO, IZO here) layer 124 and C₆₀ layer 106, which account for equivalent values of 0.64 and 0.62 mA/cm², respectively. Optimization of the top TCO and use of more transparent ETLs may further improve the photocurrent.

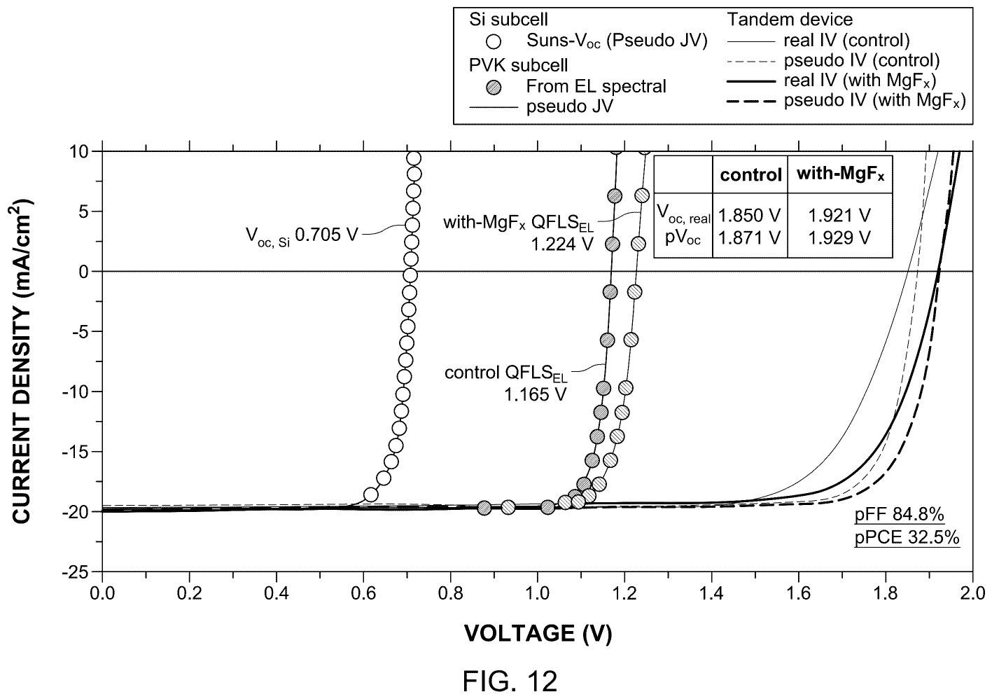

To evaluate the perovskite subcell device performance, the inventors conducted electroluminescence (EL) measurements on tandem devices. With an injected current of 22 mA/cm², the inventors observed clear EL spectral mapping with peaks positioning at around 735 nm, corresponding to the perovskite bandgap energy of ˜1.69 eV. Under any current injection condition, the MgFₓ-based tandem device 100 shows a relatively higher EL emission intensity than the control device, indicating a higher internal voltage. Combining the EL spectra results of the perovskite subcell 100A under distinct current injection conditions with the Suns-V_{oc} data of the c-Si single-junction cell 100B, the inventors were able to construct the J-V curves of the perovskite/silicon tandem device 100, as shown in FIG. 12. The J-V curves are free from any series resistance (Rs) contribution (so-called pseudo J-V curves). For the MgFₓ-based tandem cell 100, the inventors found a pseudo-V_{oc} of 1.929 V, which is remarkably close to the real V_{oc} (1.921 V) from J-V measurements. A pseudo-FF of 84.8% and pseudo-PCE of 32.5% could be also estimated, implying that about 3% in absolute PCE is still lost due to series resistance.

To explore the effect of the interlayer 102 on the device 100's stability, the inventors monitored the photovoltaic performance of the control and fluoride-based tandems without any encapsulation under continual standard AM1.5G illumination. The control device benefits from light soaking, showing a PCE increase from initially 27.2% to 28.0% after 10 min of illumination. The J-V curves (not shown) demonstrate that the light soaking leads to an improvement in V_{oc} and FF; it is believed that continuous illumination causes a slight adjustment of the energetic alignment at the perovskite/ETL interface, facilitating charge extraction to some extent. The fluoride-based devices do not seem to benefit from this, possibly due to the already improved energy-level alignment at their perovskite/ETL interface.

On a longer timescale, the LiF-based tandem shows a gradually performance drop from 29.1% to 27.5% in air, as expected, whereas the MgFₓ-based tandem cell 100 retained nearly >99% of its initial PCE after 260 min, which is due to the fact that the MgFₓ layer is a more stable non-hygroscopic material than LiF. The control device maintained a relatively stable but still lower absolute V_{oc} and FF value after light-soaking period, compared to MgFₓ-based devices.

In addition, the inventors subjected the encapsulated tandem device 100 to damp heat testing (85° C. with 85% relative humidity, RH, IEC 61215:2016 standard), which is considered as one of the harshest tests for perovskite-based devices. Remarkably, the MgFₓ-treated tandem device 100 did not show any V_{oc} or J_{sc} degradation after over 1,000 hours, and retained 95.4% of its initial PCE. The V_{oc} even improved slightly, indicating that the perovskite itself and the interfacial layers are sufficiently tolerant to thermal stress. The FF showed a slight drop, which may be related to the increase in the series resistance of the contact electrode. These results indicate that the novel tandem device 100 can withstand the most stringent industrial stability standards with only a basic encapsulation scheme.

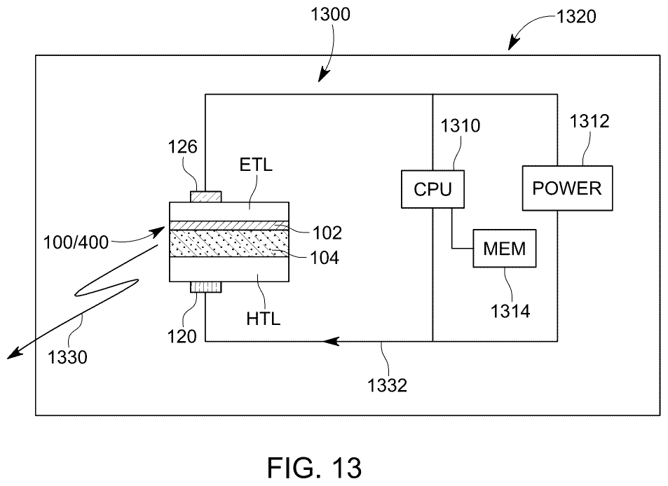

While the tandem device 100 has been discussed herein in the context of converting solar light into electricity, i.e., being used as a solar cell, those skilled in the art would understand that the same device may be used as a photodetector for transforming incoming light radiation (from the sun or from any other source) into an electrical signal. In one application, the tandem device 100 or the single junction device 400 may be used as part of a transceiver, as schematically illustrated in FIG. 13. This figure shows that the device 100/400 includes, at a minimum, the perovskite layer 104 and the MgFₓ layer 102. The device 100/400 is connected to a processor 1310 and power source 1312. The processor may be configured to encode information that needs to be transmitted by the device 100/400 as a light beam 1330 or to decode information received by the device 100/400 from a light beam. Any known encoding scheme may be used. The processor 1310 may be connected to a memory 1314 for storing the processed information from the device 100/400, or the information to be transmitted by the device 100/400. The transceiver 1300 may be part of a communication device 1320. Note that if the device 100/400 is configured to act as a transmitter, then it is configured to receive an encoded electrical signal 1332 from the processor 1310, generate the light beam 1330 at the perovskite layer, based on the encoded electrical signal 1332, and thus transmit the encoded message through the light beam 1330 to another similar device (not shown). In a different embodiment, the transceiver 1300 may be repurposed for just emitting light 1330, from a current supplied by the power source 1312, to act a light source, i.e., a light emitting device. Those skilled in the art would understand that the device 100/400 may be used for any application in which an electrical current needs to be transformed into a light beam or a light beam needs to be transformed into an electrical current or electrical signal.

The addition of the metal fluoride ultrathin layer with nonstoichiometric properties to the device 100/400 can be achieved with a conformal method of treating the perovskite films, especially the wide-bandgap perovskite films, allowing for easy translation of this process into large-area perovskite single-junction device as well as perovskite/silicon tandems. It is noted that this method uses only room-temperature processes, making it suitable for temperature-sensitive electronic/optoelectronic devices (e.g., flexible electronics). The ultrathin and highly transparent MgFₓ material, when used as the interface layer, does not generate additional parasitic absorption and does not cause optical loss in semi-transparent cells, especially in tandem devices. The MgFₓ is a more stable non-hygroscopic material than the commonly used LiF interlayer. The MgFₓ interlayer between perovskite and C₆₀ can enable improved device performance by passivating the interfacial defects, reduces the interface passivation and improves the long-term device stability simultaneously.

The MgFₓ interlayer discussed herein may be used to adjust the surface energy of the perovskite layer and mitigate the non-radiative recombination of the perovskite/ETL interface. Thus, any perovskite-based devices, such as perovskite-based light emitting diodes (LEDs), photovoltaic, and photodetectors, are potential candidates for this technology. Typically, it can be used for fabrication of high-efficiency and stable perovskite solar cells, and stable light-emitting diodes (LEDs). More and more perovskite applications in sensing, switching, transistor, and energy storage are being developed. Thus, this invention can be also expanded into these above applications.

In most cases, an ultra-thin MgFₓ film can be deposited by thermal evaporation, providing a uniform and conformal coverage onto perovskite film before ETL deposition. In addition, electron beam evaporation, as well as other physical vapor deposition, can also be used to prepare MgFₓ thin films.

The disclosed embodiments provide a tandem solar cell, single junction solar cell, light sensor, transmitter, or light emitting device that has a metal fluoride layer located directly on top of a perovskite material for reducing a voltage deficit at the ETL side, thus providing a good suppression of minority carrier recombination as well as a good majority carrier transport. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] A. Al-Ashouri, E. Kohnen, B. Li, A. Magomedov, H. Hempel, P. Caprioglio, J. A. Marquez, A. B. Morales Vilches, E. Kasparavicius, J. A. Smith, N. Phung, D. Menzel, M. Grischek, L. Kegelmann, D. Skroblin, C. Gollwitzer, T. Malinauskas, M. Jost, G. Matic, B. Rech, R. Schlatmann, M. Topic, L. Korte, A. Abate, B. Stannowski, D. Neher, M. Stolterfoht, T. Unold, V. Getautis, S. Albrecht, Monolithic perovskite/silicon tandem solar cell with >29% efficiency by enhanced hole extraction. Science 370, 1300-1309 (2020). doi:10.1126/science.abd4016;
[2] A. Al-Ashouri, A. Magomedov, M. ROß, M. Jošt, M. Talaikis, G. Chistiakova, T. Bertram, J. A. Márquez, E. Köhnen, E. Kasparavičius, S. Levcenco, L. Gil-Escrig, C. J. Hages, R. Schlatmann, B. Rech, T. Malinauskas, T. Unold, C. A. Kaufmann, L. Korte, G. Niaura, V. Getautis, S. Albrecht, Conformal monolayer contacts with lossless interfaces for perovskite single junction and monolithic tandem solar cells. Energy Environ. Sci. 12, 3356-3369 (2019). doi:10.1039/c9ee02268f;
[3] E. L. Unger, L. Kegelmann, K. Suchan, D. Sorell, L. Korte, S. Albrecht, Roadmap and roadblocks for the band gap tunability of metal halide perovskites. J. Mater. Chem. A 5, 11401-11409 (2017). doi:10.1039/c7ta00404d
[4] F. Peña-Camargo, P. Caprioglio, F. Zu, E. Gutierrez-Partida, C. M. Wolff, K. Brinkmann, S. Albrecht, T. Riedl, N. Koch, D. Neher, M. Stolterfoht, Halide Segregation versus Interfacial Recombination in Bromide-Rich Wide-Gap Perovskite Solar Cells. ACS Energy Lett. 5, 2728-2736 (2020). doi: 10.1021/acsenergylett.0c01104
[5] M. Stolterfoht, P. Caprioglio, C. M. Wolff, J. A. Márquez, J. Nordmann, S. Zhang, D. Rothhardt, U. Hormann, Y. Amir, A. Redinger, L. Kegelmann, F. Zu, S. Albrecht, N. Koch, T. Kirchartz, M. Saliba, T. Unold, D. Neher, The impact of energy alignment and interfacial recombination on the internal and external open-circuit voltage of perovskite solar cells. Energy Environ. Sci. 12, 2778-2788 (2019). doi:10.1039/c9ee02020a;
[6] J. S. Luo, J. X. Xia, H. Yang, L. L. Chen, Z. Q. Wan, F. Han, H. A. Malik, X. H. Zhu, C. Y. Jia, Toward high-efficiency, hysteresis-less, stable perovskite solar cells: unusual doping of a hole-transporting material using a fluorine-containing hydrophobic Lewis acid. Energy Environ. Sci. 11, 2035-2045 (2018). doi:10.1039/c8ee00036k.

1. A perovskite/silicon tandem device comprising:
a silicon layer having first and second opposite sides;
a first electrode located on the first side of the silicon layer;
a hole transport layer located on the second side of the silicon layer;
a perovskite layer located over the hole transport layer;
a metal fluoride layer located over the perovskite layer and in direct contact with the perovskite layer; and
a second electrode located over the ultrathin metal fluoride layer.

2. The tandem device of claim 1, wherein the metal fluoride layer includes magnesium fluoride.

3. The tandem device of claim 2, wherein the magnesium fluoride has a nonstoichiometric structure MgFₓ, where x is smaller than 2.

4. The tandem device of claim 3, wherein x is between 0.8 and 1.2.

5. The tandem device of claim 2, wherein a thickness of the magnesium fluoride layer is smaller than 2 nm.

6. The tandem device of claim 1, wherein the metal fluoride layer is lithium fluoride.

7. The tandem device of claim 1, wherein the first and second sides of the silicon layer are textured with pyramids.

8. The tandem device of claim 1, wherein the hole transport layer includes [2-(9H-carbazol-9-yl)ethyl]phosphonic acid, 2PACz.

9. The tandem device of claim 1, further comprising:
a fullerene layer located on the metal fluoride layer;
a SnO₂ layer located over the fullerene layer; and
an indium zinc oxide, IZO, layer located over the fullerene layer and under the first electrode.

10. The tandem device of claim 1, further comprising:
an n-doped α-Si layer and an intrinsic α-Si layer located between the hole transport layer and the second side of the silicon layer; and
a p-doped α-Si layer located between the first side of the silicon layer and the first electrode.

11. The tandem device of claim 1, wherein the perovskite layer converts solar energy into electrical pairs of electrons and holes, the metal fluoride layer extracts the electrons, and the hole transport layer extracts the holes so that the device acts as a solar cell.

12. The tandem device of claim 1, wherein the perovskite layer generates light from electrons and holes injected into the metal fluoride layer and the hole transport layer, so that the device acts as a light emitting device.

13. A transceiver for transmitting or receiving an encoded light beam, the transceiver comprising:
a tandem device configured to convert the encoded light beam into pairs or electrons and holes or to convert pairs of electrons and holes into the encoded light beam;
a processor connected to the tandem device and configured to decode the light beam when the light beam is received, and to encode the light beam when the light beam is transmitted; and
a power source configured to supply power to the tandem device and the processor,
wherein the tandem device includes:
a silicon layer having first and second opposite sides;
a first electrode located on the first side of the silicon layer;
a hole transport layer located on the second side of the silicon layer;
a perovskite layer located over the hole transport layer;
an ultrathin metal fluoride layer located over the perovskite layer and in direct contact with the perovskite layer; and
a second electrode located over the ultrathin metal fluoride layer.

14. The transceiver of claim 13, wherein the metal fluoride layer includes magnesium fluoride with a nonstoichiometric structure MgFₓ, where x is smaller than 2.

15. The transceiver of claim 14, wherein x is between 0.8 and 1.2.

16. The transceiver of claim 14, wherein a thickness of the magnesium fluoride layer is smaller than 2 nm.

17. A single junction device comprising:
a substrate;
a first electrode located over the substrate;
a hole transport layer located on the substrate;
a perovskite layer located over the hole transport layer;
an electron transport layer that includes an ultrathin metal fluoride layer located over the perovskite layer and in direct contact with the perovskite layer; and
a second electrode located over the ultrathin metal fluoride layer.

18. The device of claim 17, wherein the metal fluoride layer includes magnesium fluoride.

19. The device of claim 18, wherein the magnesium fluoride has a nonstoichiometric structure MgFₓ, where x is smaller than 2.

20. The device of claim 19, wherein x is between 0.8 and 1.2 and a thickness of the magnesium fluoride layer is smaller than 2 nm.
